(19) United States
(12) Patent Application Publication
(10) Pub. No.: US 2008/0061373 A1
(43) Pub. Date: Mar. 13, 2008

(54) SYSTEM-IN-PACKAGE TYPE STATIC RANDOM ACCESS MEMORY DEVICE AND MANUFACTURING METHOD THEREOF

(76) Inventor: Jin-Ha Park, Gyeonggi-do (KR)

Correspondence Address: SHERR & NOURSE, PLLC, 620 HERNDON PARKWAY, SUITE 200, HERNDON, VA, 20170, US

(21) Appl. No.: 11/852,046

(22) Filed: Sep. 7, 2007

(30) Foreign Application Priority Data
Sep. 12, 2006 (KR) 10-2006-0087745

(51) Int. Cl. H01L 27/092; H01L 21/8238

(52) U.S. Cl. 257/369; 438/200; 257/E27.062; 257/E21.632

(57) ABSTRACT

A device may include at least one of the following: A first substrate including a plurality of N-channel metal oxide semiconductor transistors, with the N-channel MOS transistors including an access transistor and a drive transistor. A second substrate including a plurality of P-channel metal oxide semiconductor transistors used as pull-up devices. A first connecting device formed on at least one of the first substrate and the second substrate to connect the plurality of N-channel metal oxide semiconductor transistors to the plurality of P-channel metal oxide semiconductor transistors, wherein the four N-channel metal oxide semiconductor transistors formed on the first substrate and the two P-channel metal oxide semiconductor transistors formed on the second substrate form the unit memory cell.

This application claims the benefit of Korean Patent Application No. P2006-0087745, filed on Sep. 12, 2006, which is hereby incorporated by reference in its entirety.

### BACKGROUND

A static random access memory (SRAM) is a memory device which may be employed in a latch to store data in a circuit. A SRAM may have a relatively fast operation speed and relatively low power consumption. Unlike a dynamic random access memory (DRAM), a SRAM does not need to periodically refreshed to store information.

A SRAM unit may have two pull-down devices, two access devices, and two pull-up devices. Different types of SRAM (which may be classified based on a configuration of the pull-up devices) include a full complementary metal oxide semiconductor (CMOS) type SRAM, a high load resistor (HLR) type SRAM, and a full thin film transistor (TFT) type SRAM. A full CMOS type SRAM may employ a P-channel bulk metal oxide semiconductor field effect transistor (MOSFET) as the pull-up devices. A HLR type SRAM may employ a poly-silicon layer with a high resistance as the pull-up devices. A TFT type SRAM may employ a P-channel poly-silicon thin film transistor (TFT) as the pull-up devices. Since a TFT type SRAM device may be able to significantly decrease the size of a cell, a TFT type SRAM device may be used in a semiconductor device dedicated for data storage.

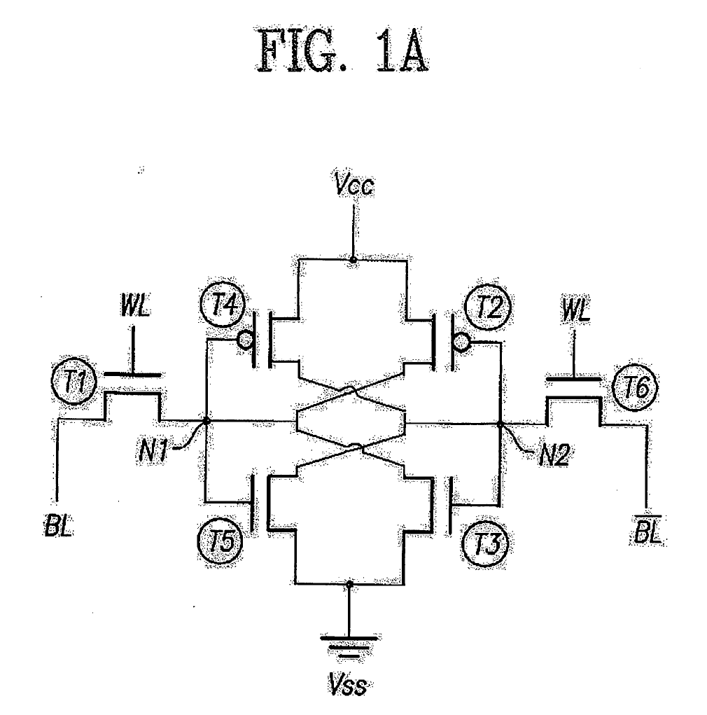

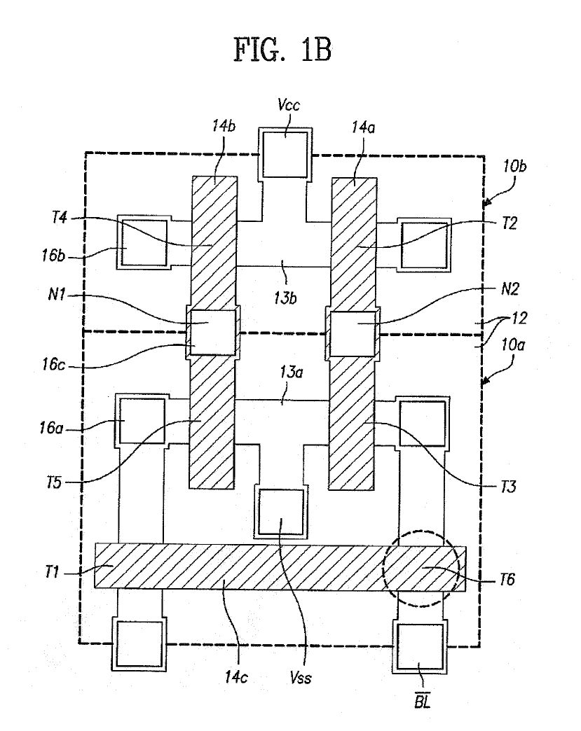

Example FIG. 1A illustrates a circuit diagram of a SRAM device. Example FIG. 1B illustrates a layout of the full CMOS type SRAM device. As illustrated in example FIG. 1A, a unit SRAM cell may include access N-channel metal oxide semiconductor (MOS) transistors T1 and T6. Transistor T1 may connect a bit line BL to first node N1 when word line WL is activated. Transistor T2 may connect bit line B̅L̅ to a second node N2 of a memory cell when a word line WL is activated. A unit SRAM cell may include P-channel MOS transistors T2 and T4. Transistor T4 may connect power source voltage Vcc to node N1. Transistor T2 may connect power source voltage Vcc to node N2. A unit SRAM cell may include drive N-channel MOS transistors T3 and T5. Transistor T3 may connect node N2 to ground Vss. Transistor T5 may connect node N1 to ground Vss.

P-channel MOS transistor T2 and drive N-channel MOS transistor T3 may be controlled by a signal at second node N2 to supply power source voltage Vcc or ground Vss to the first node N1. Similarly, P-channel MOS transistor T4 and drive N-channel MOS transistor T5 may be controlled by a signal at first node N1 to supply power source voltage Vcc or ground Vss to second node N2. N-channel MOS transistor T1 (e.g. an access device), drive N-channel MOS transistor T3 (e.g. a pull-down device), and P-channel MOS transistor T2 (e.g. a pull-up device) are connected at first node N1 to store data. Likewise, N-channel MOS transistor T6, drive N-channel MOS transistor T5, and P-channel MOS transistor T4 are connected at second node N2 to store data.

As illustrated in example FIG. 1B, in order to form N-channel MOS transistors (e.g. transistors T1, T3, T5, and T6) and P-channel MOS transistors (e.g. T2 and T4), a P-well 10a and an N-well 10b are formed in a semiconductor substrate. Active regions 13a and 13b may be defined by device separation film 12. A plurality of poly-silicon layers 14a, 14b, and 14c may cross active regions 13a and 13b. An N-type dopant may be injected into active region 13a in P-well 10a to form N-channel MOS transistors. Likewise, a P-type dopant may be injected into active region 13b in N-well 10b to form P-channel MOS transistors. Transistors T1, T2, T3, T4, T5, and T6 are illustrated in example FIG. 1B. Gate and source/drain regions of the respective transistors may be connected to upper metal wires via contacts 16a, 16b, and 16c or to each other via silicides formed on the poly-silicon layers 14a and 14b.

In order to manufacture a SRAM device of example FIG. 1B, several ion injections may be performed. For example, an ion injection may need to be performed twice to form the N-well and the P-well (i.e. once for the N-well and once for the P-well). In order to form channels in the N-channel and P-channel MOS transistors, the ion injections must be carried out twice. Further, in order to form a lightly dope drain (LDD), the two ion injections must be additionally carried out. Accordingly, in order to manufacture a SRAM device, a total of six basic ion injections may need to be carried out. For each ion injection various detailed processes (e.g. photographing for opening the ion injection regions, an ion injection for injecting a dopant, ashing to remove a photosensitive film used as a mask, cleaning using acid sulfide to remove a polymer remaining after ashing) may need to be performed. Accordingly, the structure illustrated in example FIG. 1B requires a relatively large number of processes because both N-channel MOS transistors and the P-channel MOS transistors are formed on the same substrate, making the manufacturing process relatively complicated.

### SUMMARY

Embodiments relate to a system-in-package (SiP) type static random access memory (SRAM) device. Embodiments relate to a method of manufacturing a SRAM device that is relatively simple. In embodiments, a SiP type SRAM device may be manufactured with minimal ion injection and photographing processes.

In embodiments, a unit memory cell of a static random access memory device may include four N-channel metal oxide semiconductor transistors and two P-channel metal oxide semiconductor transistors. In embodiments, a device may include at least one of the following: A first substrate including a plurality of N-channel metal oxide semiconductor transistors, with the N-channel MOS transistors including an access transistor and a drive transistor. A second substrate including a plurality of P-channel metal oxide semiconductor transistors used as pull-up devices. A first connecting device formed on at least one of the first substrate and the second substrate to connect the plurality of N-channel metal oxide semiconductor transistors to the plurality of P-channel metal oxide semiconductor transistors, wherein the four N-channel metal oxide semiconductor transistors formed on the first substrate and the two P-channel metal oxide semiconductor transistors formed on the second substrate form the unit memory cell.

Embodiments relate to a method of manufacturing a static random access memory device in which a unit memory cell includes four N-channel metal oxide semiconductor transistors and two P-channel metal oxide semiconductor transistors. In embodiment, the method may include at least one of the following steps: Forming a plurality of N-channel metal oxide semiconductor transistors to form an access transistor and a drive transistor on a first substrate. Forming a plurality of P-channel metal oxide semiconductor transistors used as pull-up devices on a second substrate. Laminating the first substrate and the second substrate such that the plurality of the N-channel metal oxide semiconductor transistors are connected to the plurality of the P-channel metal oxide semiconductor transistors.

### DRAWINGS

Example FIG. 1A is a circuit diagram illustrating a unit cell of a static random access memory device.

Example FIG. 1B is a layout illustrating a unit cell of a status random access memory device.

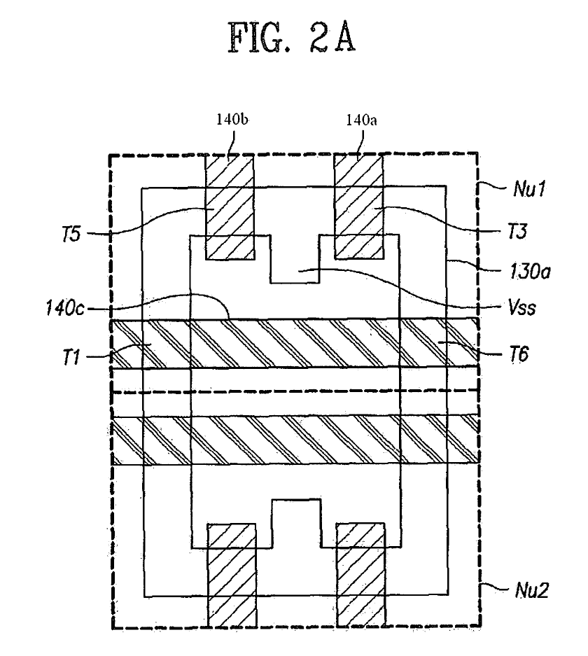

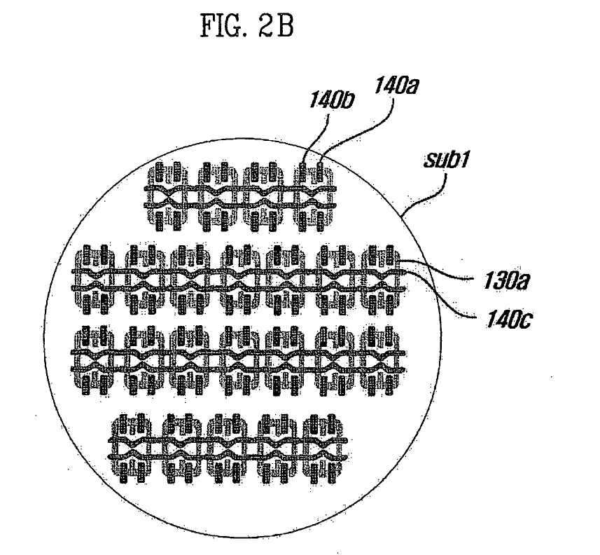

Example FIG. 2A is a layout illustrating two unit N-channel metal oxide semiconductor (NMOS) cells of a static random access memory device, according to embodiments.

Example FIG. 2B is a plan view illustrating a plurality NMOS cell units formed on a first semiconductor substrate, in accordance with embodiments.

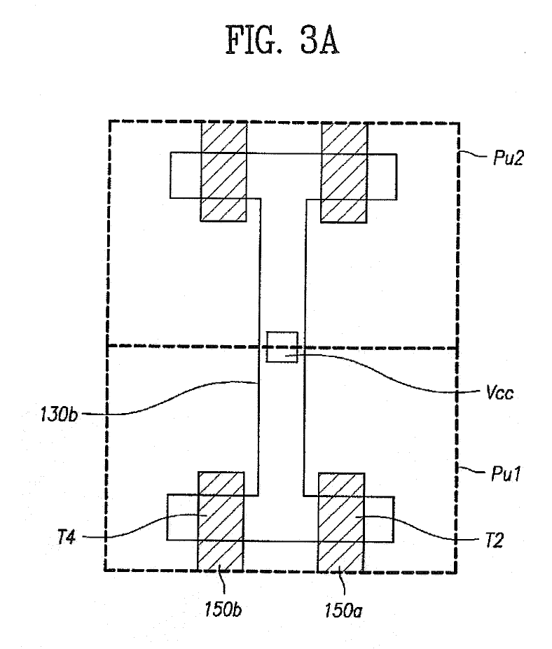

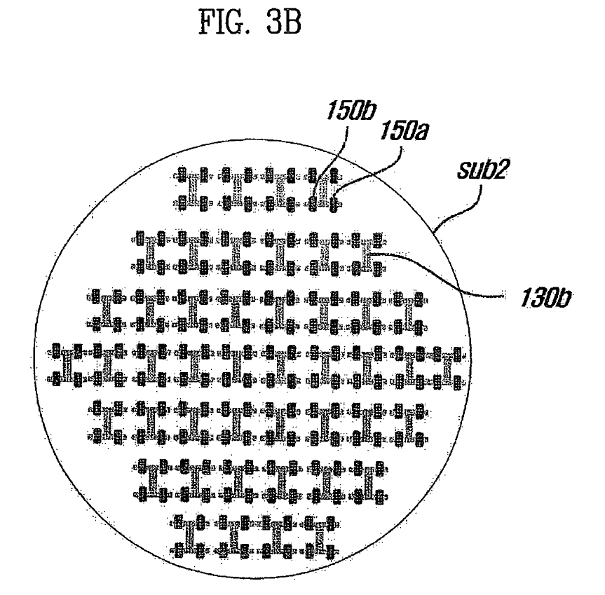

Example FIG. 3A is a layout illustrating two P-channel metal oxide semiconductor (PMOS) cell units of a SRAM device, according to embodiments.

Example FIG. 3B is a plan view illustrating a plurality of PMOS cell units formed on a second semiconductor substrate, in accordance with embodiments.

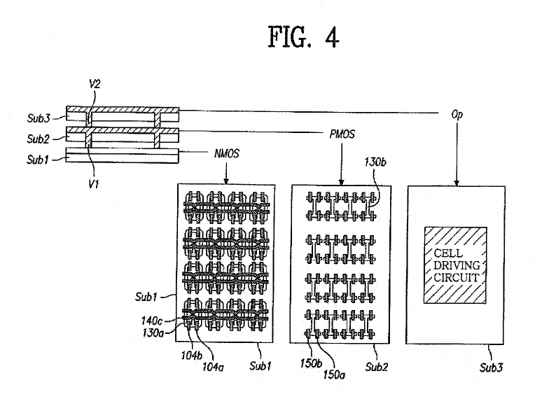

Example FIG. 4 is a schematic view illustrating a system-in-chip type SRAM device formed by laminating a plurality of semiconductor substrates, according to embodiments.

### DESCRIPTION

Example FIG. 4 illustrates a static random access memory (SRAM) device, in accordance with embodiments. First substrate Sub1 may include a plurality of N-channel metal oxide semiconductor (NMOS) units. Each unit of first substrate Sub1 may include four NMOS transistors to form access transistors and drive transistors. Second substrate Sub2 may include a plurality of P-channel metal oxide semiconductor (PMOS) units. Each unit of second substrate Sub2 may include two PMOS transistors used as pull-up devices. In embodiments, a PMOS unit (e.g. two PMOS transistors) of second substrate Sub2 may be coupled with a corresponding NMOS unit (e.g. four NMOS transistors) of first substrate Sub1 to form a memory cell unit.

In embodiments, first substrate Sub1 and second substrate Sub2 are laminated together in the system-in-package (SiP) formation process. In embodiments, penetration electrode V1 may be formed in second substrate Sub2 to connect PMOS transistors formed on second substrate Sub2 to NMOS transistors formed on first substrate Sub1. In embodiments, a cell driving circuit (e.g. which may drive SRAM memory devices) may be formed on third substrate Sub3. A cell driving circuit may be connected to second substrate Sub2 using a SiP type penetration electrode V2.

A SRAM device may be formed by laminating a plurality of semiconductor substrates to form memory cell units in a SiP configuration, such that transistors in a memory cell unit are divided among the plurality of semiconductor substrates. By dividing transistors in a memory cell unit among different substrates, the number of ion injection and the photographing processes may be minimized. For example, the number of masks to inject ions may be reduced by a factor of 3 and there may be a significant minimization of the number of photographing processes using a photosensitive film. In embodiments, the number of processes may be minimized because NMOS and PMOS transistors are not formed on the same substrate.

As illustrated in example FIGS. 2A and 2B, a unit NMOS cell Nu1 formed on first substrate Sub1 may include two access transistors T1 and T6 and two drive transistors T3 and T5, in accordance with embodiments. Unit NMOS cell Nu1 may be formed by a method of manufacturing a semiconductor device. Since PMOS transistors are not formed on first substrate Sub1, only processes required to form the NMOS transistors may be performed. In embodiments, a unit NMOS cell Nu1 may be symmetrical to a unit cell Nu2 and active regions 130a may be repeatedly formed in the same patterns. A word line may be formed by a poly-silicon layer 140c and respective access transistors T1 and T6 may be formed where the word line intersects active regions 130a. In a unit cell, other poly-silicon layers 140a and 140b may form drive transistors T5 and T3.

As illustrated in example FIGS. 3A and 3B, a plurality of PMOS transistors formed on semiconductor substrate Sub2 may be used as pull-up devices, in accordance with embodiments. As illustrated in FIG. 3A, two respective PMOS transistors T2 and T4 may be formed in PMOS cell units Pu1 and Pu2. In embodiments, PMOS transistors T2 and T4 may be formed in regions where the active region 130b intersects poly-silicon layers 150a and 150b.

As illustrated in example FIGS. 2A and 3A, two NMOS cells units Nu1 and Nu2 (i.e. FIG. 2A) and two PMOS cells units Pu1 and Pu2 (i.e. FIG. 3A) are formed. However, one of ordinary skill in the art would appreciate other numbers of units (including a single unit). In embodiments, a plurality of unit patterns may be repeatedly formed on semiconductor substrates Sub1 and Sub2, as illustrated in example FIGS. 2B and 3B. In embodiments, a unit NMOS cell Nu1 in FIG. 2A may be connected to a unit PMOS cell Pu1 in FIG. 3A to form a single unit SRAM memory cell.

As illustrated in FIG. 4, first substrate Sub1 and second substrate Sub2 are laminated and a unit NMOS cell is connected to a unit PMOS cell by a penetration electrode V1. A unit SRAM memory cell may be formed by four NMOS transistors (e.g. T1, T3, T5, and T6) formed on first substrate Sub1 and two PMOS transistors (e.g. T2 and T4) formed on second substrate Sub2. In embodiments, first substrate Sub1 and second substrate Sub2 may be laminated by SiP manufacturing processes.

As illustrated in FIG. 4, a driving circuit Op formed on third substrate Sub3 may drive the memory cell in first substrate Sub1 and second substrate Sub2, in accordance with embodiments. In embodiments, third substrate Sub3 may be laminated on the second substrate Sub2. Third substrate Sub3 may be laminated by a SiP processing method. Penetration electrode V2 may be formed in third substrate Sub3.

In embodiments, NMOS transistors and the PMOS transistors may form a memory cell unit of the SRAM device, with the NMOS transistors formed on a different substrate than the PMOS transistors. A substrate including the NMOS transistors may be laminated to a substrate including the PMOS transistors by a SiP processing method to form a memory cell unit. Since it may not be necessary to form NMOS and PMOS transistors on the same substrate, masking processes may not need be performed to distinguish the NMOS transistors from the PMOS transistors. Accordingly, the ion injection and photographing processes may be minimized.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprises:
a first substrate comprising at least one N-channel metal oxide semiconductor transistor; and
a second substrate comprises at least one P-channel metal oxide semiconductor transistor, wherein said at least one N-Channel metal oxide semiconductor transistor and said at least one P-channel metal oxide semiconductor transistor comprise a memory cell unit.

2. The apparatus of claim 1, wherein the memory cell unit is a static random access memory cell unit.

3. The apparatus of claim 1, wherein said at least one N-channel metal oxide semiconductor transistor comprises four N-channel metal oxide semiconductor transistors.

4. The apparatus of claim 3, wherein said four N-channel metal oxide semiconductor transistors comprises an access transistor and a drive transistor.

5. The apparatus of claim 1, wherein said at least one P-channel metal oxide semiconductor transistor comprises two P-channel metal oxide semiconductor transistors.

6. The apparatus of claim 5, wherein said two P-channel metal oxide semiconductor transistors comprise pull-up devices.

7. The apparatus of claim 1, comprising a first connecting device formed on at least one of the first substrate and the second substrate to connect said at least one N-channel metal oxide semiconductor transistor and said at least one P-channel metal oxide semiconductor transistor.

8. The apparatus of claim 1, comprising a third substrate, wherein the third substrate comprises:
a driving circuit to drive the memory cell unit; and
a second connecting device to connect the driving circuit to the unit memory cell.

9. The apparatus of claim 8, wherein at least one of the first connecting device and the second connecting device are system-in-package type through-hole electrodes.

10. The apparatus of claim 1, wherein the first substrate and the second substrate are laminated together in a system-in-package configuration.

11. A method comprises:
forming at least one N-channel metal oxide semiconductor transistor on a first substrate; and
forming at least one P-channel metal oxide semiconductor transistor on a second substrate, wherein said at least one N-Channel metal oxide semiconductor transistor and said at least one P-channel metal oxide semiconductor transistor comprise a memory cell unit.

12. The method of claim 11, wherein the memory cell unit is a static random access memory cell unit.

13. The method of claim 11, wherein said at least one N-channel metal oxide semiconductor transistor comprises four N-channel metal oxide semiconductor transistors.

14. The method of claim 13, wherein said four N-channel metal oxide semiconductor transistors comprises an access transistor and a drive transistor.

15. The method of claim 11, wherein said at least one P-channel metal oxide semiconductor transistor comprises two P-channel metal oxide semiconductor transistors.

16. The method of claim 15, wherein said two P-channel metal oxide semiconductor transistors comprise pull-up devices.

17. The method of claim 11, comprising forming a first connecting device on at least one of the first substrate and the second substrate to connect said at least one N-channel metal oxide semiconductor transistor and said at least one P-channel metal oxide semiconductor transistor.

18. The method of claim 11, comprising forming a third substrate, wherein the third substrate comprises:
a driving circuit to drive the memory cell unit; and
a second connecting device to connect the driving circuit to the unit memory cell.

19. The method of claim 18, wherein at least one of the first connecting device and the second connecting device are system-in-package type through-hole electrodes.

20. The method of claim 11, comprising laminating the first substrate and the second substrate together into a system-in-package configuration.
